(19) United States
(12) Patent Application Publication
(10) Pub. No.: US 2014/0096377 A1
(43) Pub. Date: Apr. 10, 2014

(54) METHOD OF MANUFACTURING RIGID-FLEXIBLE PRINTED CIRCUIT BOARD

(71) Applicant: SAMSUNG ELECTRO-MECHANICS CO., LTD., Suwon-si (KR)

(72) Inventors: Jung-Yong Park, Suwon (KR); Jung-Woo KIM, Suwon (KR)

(73) Assignee: SAMSUNG ELECTRO-MECHANICS CO., LTD., Suwon-si (KR)

(21) Appl. No.: 14/044,420

(22) Filed: Oct. 2, 2013

(30) Foreign Application Priority Data
Oct. 10, 2012 (KR) 10-2012-0112195

(51) Int. Cl. H05K 3/36

(52) U.S. Cl. CPC H05K 3/361
USPC 29/830

(57) ABSTRACT

A method of manufacturing a rigid-flexible printed circuit board in accordance with an embodiment of the present invention includes: providing a pair of rigid boards and a flexible substrate inserted in between the pair of rigid boards and having one end thereof extended outside the pair of rigid boards; mounting a cover film on an extended area of the flexible substrate; providing a pair of pressing jigs disposed, respectively, above and below the rigid boards and the flexible substrate, having a protruded part formed on each thereof corresponding to a step difference between the rigid boards and the flexible substrate, and configured to press the pair of rigid boards and the flexible substrate and press the flexible substrate and the cover film mounted thereon; and pressing the rigid boards, the flexible substrate and the cover film with the pressing jigs.

### CROSS-REFERENCE TO RELATED APPLICATIONS

This application claims the benefit of Korean Patent Application No. 10-2012-0112195, filed with the Korean Intellectual Property Office on Oct. 10, 2012, the disclosure of which is incorporated herein by reference in its entirety.

### BACKGROUND

1. Technical Field

The present invention relates to a method of manufacturing a rigid-flexible printed circuit board.

2. Background Art

As the electronics industry has recently experienced technological advancements in integrating semiconductor integrated circuits, surface mounting small chip components directly and making electronic apparatuses smaller, it has been increasingly necessary to provide a printed circuit board that can be easily installed in a smaller and more complex space. Developed to meet this demand is a flexible printed circuit board (FPCB).

Owing to the advancement of electronic apparatuses such as portable terminals, LCDs, PDPs, cameras, printer heads, etc., the demand for the FPCB has been dramatically increased. Moreover, use of rigid-flexible printed circuit board has been rapidly increased recently in order to achieve high-density circuit boards.

Among the flexible printed circuit boards, a double side flexible circuit board is fabricated by: laminating a dry film on a flexible copper clad laminate (FCCL), in which copper foils are formed on either surface of an insulating film such as polyimide resin; forming a circuit pattern through successive exposing, developing and etching processes; and attaching and hot-pressing a coverlay film on an outside of the FCCL.

The FCCL, which is the material for the FPCB, is fabricated by the laminating method, in which an insulating film and a copper foil are attached to each other by use of adhesive, the casting method, in which varnish is coated and hardened on a copper foil, and the sputtering and electroplating method, in which an insulating film is vacuum deposited with a copper seed layer thereon and then electroplated.

As the electronic products become increasingly smaller and their components are more integrated, the line widths of their circuits and flexible printed circuit boards need to be much finer, and accordingly the copper foil of the FCCL needs to be adjusted to be increasingly thinner.

The related art of the present invention is disclosed in Korea Patent No. 10-1008479 (RIGID-FLEXIBLE PRINTED CIRCUIT BOARD AND METHOD FOR MANUFACTURING THEREOF; registered on Jan. 7, 2011).

### SUMMARY

The present invention provides a method of manufacturing a rigid-flexible printed circuit board that can prevent a material attached to a flexible board from splitting off by use of a pressing jig having a protruded part formed thereon.

The method of manufacturing a rigid-flexible printed circuit board in accordance with an embodiment of the present invention can include: providing a pair of rigid boards and a flexible substrate inserted in between the pair of rigid boards and having one end thereof extended outside the pair of rigid boards; mounting a cover film on an extended area of the flexible substrate; providing a pair of pressing jigs disposed, respectively, above and below the rigid boards and the flexible substrate, having a protruded part formed on each thereof corresponding to a step difference between the rigid boards and the flexible substrate, and configured to press the pair of rigid boards and the flexible substrate and press the flexible substrate and the cover film mounted thereon; and pressing the rigid boards, the flexible substrate and the cover film with the pressing jigs.

The protruded part can be formed in such a way that a sum of thicknesses of the protruded part of the pair of pressing jigs and the cover film is the same as a thickness of the pair of rigid boards.

The pressing jig can be made of aluminum.

The protruded part formed on the pressing jig can be formed through an end-mill processing.

After the mounting of the cover film, a pair of flexible subsidiary members disposed, respectively, above and below the rigid boards and the flexible substrate can be provided.

After the step of pressing, the subsidiary members and the pressing jigs can be removed.

The cover film can be an EMI (electromagnetic interference) shield film.

### BRIEF DESCRIPTION OF THE DRAWINGS

FIG. 1 is a brief illustration of a method of manufacturing a rigid-flexible printed circuit board in accordance with an embodiment of the present invention.

FIG. 2 is a brief illustration of how a protruded part of a pressing jig is formed in the method of manufacturing a rigid-flexible printed circuit board in accordance with an embodiment of the present invention.

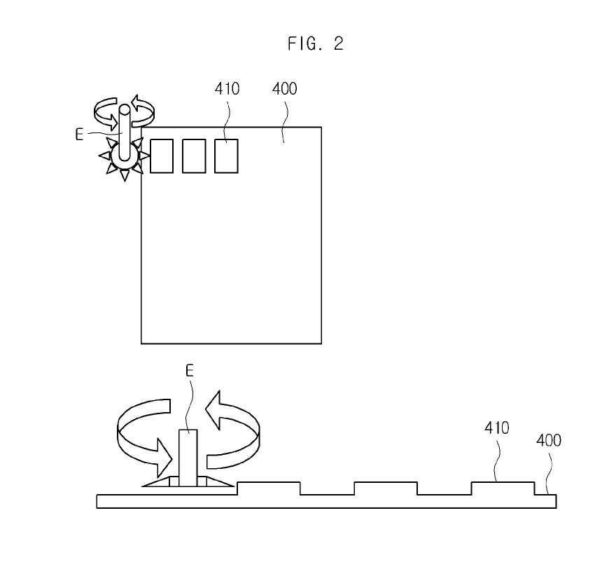

### DETAILED DESCRIPTION

Since there can be a variety of permutations and embodiments of the present invention, certain embodiments will be illustrated and described with reference to the accompanying drawings. This, however, is by no means to restrict the present invention to certain embodiments, and shall be construed as including all permutations, equivalents and substitutes covered by the ideas and scope of the present invention. Throughout the description of the present invention, when describing a certain technology is determined to evade the point of the present invention, the pertinent detailed description will be omitted.

Terms such as “first” and “second” can be used in describing various elements, but the above elements shall not be restricted to the above terms. The above terms are used only to distinguish one element from the other.

The terms used in the description are intended to describe certain embodiments only, and shall by no means restrict the present invention. Unless clearly used otherwise, expressions in a singular form include a meaning of a plural form. In the present description, an expression such as “comprising” or “including” is intended to designate a characteristic, a number, a step, an operation, an element, a part or combinations thereof, and shall not be construed to preclude any presence or possibility of one or more other characteristics, numbers, steps, operations, elements, parts or combinations thereof.

Hereinafter, a method of manufacturing a rigid-flexible printed circuit board in accordance with an embodiment of the present invention will be described in detail with reference to the accompanying drawings. In describing a certain embodiment of the present invention with reference to the accompanying drawings, any identical or corresponding elements will be assigned with same reference numerals, and their redundant description will not be provided.

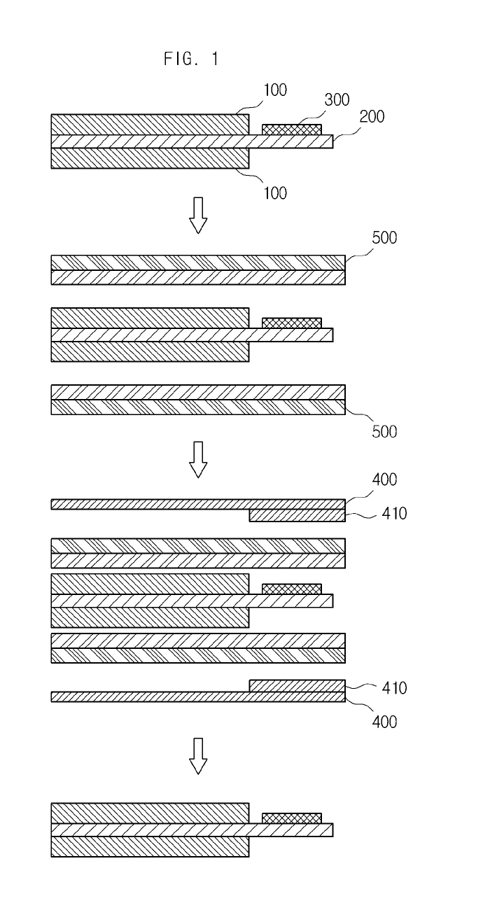

As illustrated in FIG. 1, a method of manufacturing a rigid-flexible printed circuit board in accordance with an embodiment of the present invention includes a step of providing a board, a step of mounting a film, a step of providing a jig and a step of pressing.

In the step of providing a board, a board including a pair of rigid boards 100 and a flexible substrate 200 is provided, and the flexible substrate 200 can be interposed between the pair of rigid boards 100.

Here, one end of the flexible substrate 200 is extended and protruded outside the pair of rigid boards 100.

In the step of mounting a film, a cover film 300 is mounted on a portion of the flexible substrate 200 that is extended and protruded outside the rigid boards 100.

Here, the cover film 300 can be an EMI shield film that shields electromagnetic waves.

In the step of providing a jig, a pair of pressing jigs 400 are provided for pressing the pair of rigid boards 100 and the flexible substrate 200 inserted in between the pair of rigid boards 100.

Here, a step difference is formed due to a difference in height between the pair of rigid boards 100 and the flexible substrate 200 inserted in between the pair of rigid boards 100, and accordingly the film mounted on the flexible substrate 200 may not be properly pressed due to this step difference.

To solve this problem, in the method of manufacturing a rigid-flexible printed circuit board in accordance with an embodiment of the present invention, a protruded part 410 can be formed at a portion of the pressing jig 400 corresponding to the step difference.

The protruded part 410 can be formed in such a way that a sum of thicknesses of the protruded part 410 of the pair of pressing jigs 400 and the cover film 300 is the same as a thickness of the pair of rigid boards 100 so that the cover film 300 mounted on the portion of the flexible substrate 200 can be properly pressed when the pair of rigid boards 100 and the flexible substrate 200 inserted therein are pressed together.

Preferably, a thickness of the protruded part 410 of the pressing jig 400 on a side of the cover film 300 formed on the flexible substrate 200 is the same as a thickness of the rigid board 100 on a side of the cover film 300 subtracted by a thickness of the cover film 300, and a thickness of the protruded part 410 of the pressing jig 400 on a side of the flexible substrate 200 where the cover film 300 is not formed is the same as a thickness of the rigid board 100 on a side where the cover film 300 is not formed, so that the cover film 300 mounted on the portion of the flexible substrate 200 can be properly pressed when the pair of rigid boards 100 and the flexible substrate 200 inserted therein are pressed together.

In the step of pressing, the pair of pressing jigs 400 are placed over and below the rigid board 100 and the flexible substrate 200 to press the rigid board 100 and the flexible substrate 200 together, and accordingly the flexible substrate 200 and the cover film 300 mounted on the flexible substrate 200 are pressed.

In other words, by pressing the rigid board 100 and the flexible substrate 200 with the pair of pressing jigs 400 from thereabove and therebelow, respectively, the rigid board 100 can be pressed to the flexible substrate 200, and the cover film 300 can be also pressed to and mounted on the flexible substrate 200 without any gap therebetween.

Here, the pressing jig 400 can be made of aluminum.

If the protruded part 410 is formed by manually attaching aluminum having predetermined shape(s) to a flat pressing jig 400, it is difficult and takes a long time to fabricate the protruded part 410, and tolerance and positional deviation may be occurred due to the manual operation, possibly resulting in defect in some product.

Therefore, in the present invention, the protruded part 410 formed on the pressing jig 400 can be formed at a location desired by an operator through an end-mill (E) processing.

That is, it is possible to easily form the protruded part 410 in a number and at locations corresponding to cover film(s) 300 mounted on the flexible substrate 200 by use of the end-mill (E) processing.

The pressing jig 400 in accordance with an embodiment of the present invention has the protruded part 400 formed at desired location(s) by processing an external form of an aluminum jig itself and thus can improve the workability and significantly reduce the defect ratio through a precise and speedy operation.

Another embodiment of the present invention can additionally include a step of providing a subsidiary member 500, in which a pair of flexible subsidiary members 500 are disposed above and below the rigid board 100 and the flexible substrate 200, after the step of mounting a film.

That is, the pair of subsidiary members 500 can be placed above and below the rigid board 100 and the flexible substrate 200, and the pair of pressing jigs 400 can be placed above and below the pair of subsidiary members 500, respectively.

Here, the pair of subsidiary members 500 are pressed by the pair of pressing jigs 400, and since the pair of subsidiary members 500 are flexible, the subsidiary members 500 can be bent toward a space where the step difference is formed between the rigid board 100 and the flexible substrate 200 to press the cover film 300 and the flexible substrate 200.

The method of manufacturing a rigid-flexible printed circuit board in accordance with another embodiment of the present invention further includes a step of completing.

In the step of completing, the subsidiary member 500 and the pressing jig 400 are removed, after the step of pressing, to complete a product.

Accordingly, despite the step difference between the rigid board 100 and the flexible substrate 200, the cover film 300 can be mounted on the flexible substrate 200 without any gap therebetween using the pressing jig 400 having the protruded part 410 formed thereon by the end-mill (E), and the manufacturing cost and time can be saved.

Although certain embodiments of the present invention have been described, it shall be appreciated that there can be a very large number of permutations and modification of the present invention by those who are ordinarily skilled in the art to which the present invention pertains without departing from the technical ideas and boundaries of the present invention, which shall be defined by the claims appended below.

It shall be also appreciated that many other embodiments other than the embodiments described above are included in the claims of the present invention.

1. A method of manufacturing a rigid-flexible printed circuit board, comprising:
providing a pair of rigid boards and a flexible substrate inserted in between the pair of rigid boards and having one end thereof extended outside the pair of rigid boards;
mounting a cover film on an extended area of the flexible substrate;
providing a pair of pressing jigs disposed, respectively, above and below the rigid boards and the flexible substrate, having a protruded part formed on each thereof corresponding to a step difference between the rigid boards and the flexible substrate, and configured to press the pair of rigid boards and the flexible substrate and press the flexible substrate and the cover film mounted thereon; and
pressing the rigid boards, the flexible substrate and the cover film with the pressing jigs.

2. The method of claim 1, wherein the protruded part is formed in such a way that a sum of thicknesses of the protruded part of the pair of pressing jigs and the cover film is the same as a thickness of the pair of rigid boards.

3. The method of claim 1, wherein the pressing jig is made of aluminum.

4. The method of claim 3, wherein the protruded part formed on the pressing jig is formed through an end-mill processing.

5. The method of claim 1, further comprising, after the mounting of the cover film, providing a pair of flexible subsidiary members disposed, respectively, above and below the rigid boards and the flexible substrate.

6. The method of claim 5, further comprising, after the stop of pressing the rigid boards, removing the subsidiary members and the pressing jigs.

7. The method of claim 1, wherein the cover film is an EMI (electromagnetic interference) shield film.
